(19) United States
(12) Patent Application Publication
(10) Pub. No.: US 2026/0265155 A1
(43) Pub. Date: Sep. 10, 2026

(54) CERAMIC SUBSTRATE, ELECTROSTATIC CHUCK, SUBSTRATE FIXING DEVICE, AND CONDUCTIVE PASTE

(71) Applicant: SHINKO ELECTRIC INDUSTRIES CO., LTD., Nagano-shi (JP)

(72) Inventors: Ryosuke Hori, Nagano (JP); Tomotake Minemura, Nagano (JP); Koji Nagai, Nagano (JP); Yuichiro Shimizu, Nagano (JP); Michio Horiuchi, Nagano (JP); Shunsuke Aoki, Nagano (JP)

(21) Appl. No.: 19/556,483

(22) Filed: Mar. 4, 2026

(30) Foreign Application Priority Data
Mar. 5, 2025 (JP) 2025-034299

(51) Int. Cl. C04B 41/51; C04B 35/10; C04B 41/45; C09D 11/037; C09D 11/52; H01J 37/32; H10P 72/72

(52) U.S. Cl. CPC C04B 41/5133; C04B 35/10; C04B 41/4576; C04B 41/5138; C09D 11/037; C09D 11/52; H01J 37/32715; H10P 72/722; H01J 2237/2007; H01J 2237/334

(57) ABSTRACT

A ceramic substrate includes a base formed of ceramic, and a conductor pattern embedded in the base and containing tungsten, molybdenum, or both. The conductor pattern includes a first aluminum oxide crystal grain having a crystal grain size of less than 1 μm, a second aluminum oxide crystal grain having a crystal grain size of 1 μm or more and less than 3 μm, and a third aluminum oxide crystal grain having a crystal grain size of 3 μm or more.

### CROSS-REFERENCE TO RELATED APPLICATIONS

This application claims priority from Japanese Patent Application No. 2025-034299, filed on Mar. 5, 2025, the entire content of which is incorporated herein by reference.

### TECHNICAL FIELD

The present disclosure relates to a ceramic substrate, an electrostatic chuck, a substrate fixing device, and a conductive paste.

### BACKGROUND ART

In the related art, a film forming device and a plasma etching device used for manufacturing a semiconductor device each include a stage for accurately holding a substrate such as a silicon wafer in a vacuum processing chamber. As the stage, for example, a substrate fixing device that adsorbs and holds a substrate by an electrostatic chuck mounted on a base plate has been proposed.

The electrostatic chuck includes a base body formed of ceramic and an electrode embedded in the base body, and is formed by, for example, simultaneous firing of a green sheet containing ceramic and a conductive paste containing a high melting point metal such as tungsten. The conductive paste contains nickel oxide, aluminum oxide, and silicon dioxide as sintering aids.

### SUMMARY OF INVENTION

In recent years, there has been an increasing demand for improvement in volume resistivity of the base body.

An object of the present disclosure is to provide a ceramic substrate, an electrostatic chuck, a substrate fixing device, and a conductive paste capable of improving volume resistivity of a base body.

According to one aspect of the present disclosure, a ceramic substrate includes a base body formed of ceramic, and a conductor pattern embedded in the base body and containing tungsten, molybdenum, or both. The conductor pattern includes a first aluminum oxide crystal grain having a crystal grain size of less than 1 μm, a second aluminum oxide crystal grain having a crystal grain size of 1 μm or more and less than 3 μm, and a third aluminum oxide crystal grain having a crystal grain size of 3 μm or more.

According to the present disclosure, the volume resistivity of the base body can be improved.

### BRIEF DESCRIPTION OF DRAWINGS

FIG. 1 is a graph illustrating the relationship between temperature and volume resistivity of alumina.

FIG. 2 is a graph (part 1) illustrating the relationship between temperature and volume resistivity of a test coupon.

FIG. 3 is a cross-sectional view illustrating the test coupon.

FIGS. 4A and 4B are diagrams (part 1) illustrating results of an EPMA analysis of silicon.

FIG. 5 is a diagram (part 1) illustrating results of SEM observation.

FIG. 6 is a diagram illustrating volume resistivity of a conductor pattern.

FIGS. 7A and 7B are diagrams (part 2) illustrating results of the EPMA analysis of silicon.

FIGS. 8A and 8B are diagrams (part 2) illustrating results of the SEM observation.

FIG. 9 is a graph (part 2) illustrating the relationship between the temperature and the volume resistivity of the test coupon.

FIGS. 10A and 10B are views each illustrating a substrate fixing device according to an embodiment.

FIG. 11 is a graph illustrating the distribution of the crystal grain size of aluminum oxide contained in an electrostatic electrode.

FIGS. 12A to 12C are perspective views (part 1) illustrating a manufacturing process of an electrostatic chuck according to the embodiment.

FIGS. 13A to 13C are perspective views (part 2) illustrating the manufacturing process of the electrostatic chuck according to the embodiment.

FIG. 14 a diagram illustrating a conductive paste.

FIG. 15 is a diagram illustrating results of a tensile test.

### DESCRIPTION OF EMBODIMENTS

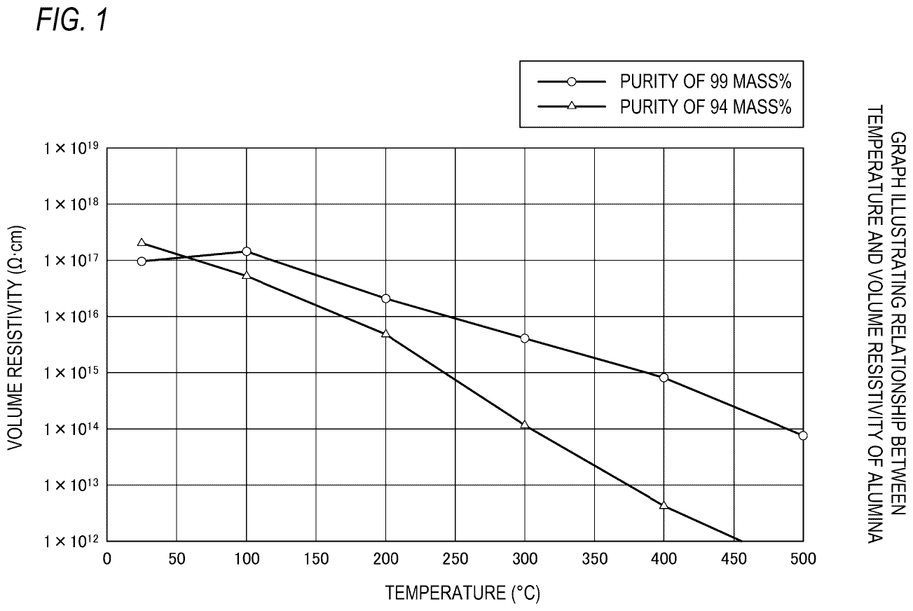

In order to improve the volume resistivity of the ceramic base body, it is effective to improve the purity of the ceramic in the ceramic base body. For example, in high-purity alumina having a purity of 99 mass % or more, as illustrated in FIG. 1, a volume resistivity higher than that of alumina having a purity of 94 mass % is obtained in a wide temperature range. The volume resistivity of the ceramic base body of an electrostatic chuck is preferably 1×10¹⁵ Ω·cm or more at a temperature of about 150° C. FIG. 1 is a diagram illustrating the relationship between temperature and volume resistivity of alumina.

The ceramic base body of high-purity alumina can be formed by solid-phase sintering using a green sheet not containing a sintering aid. However, in the case of using the green sheet not containing the sintering aid, when an electrostatic electrode provided in the electrostatic chuck is formed simultaneously with a ceramic base body, the sintering aid is required for a conductive paste, which is a material of the electrostatic electrode.

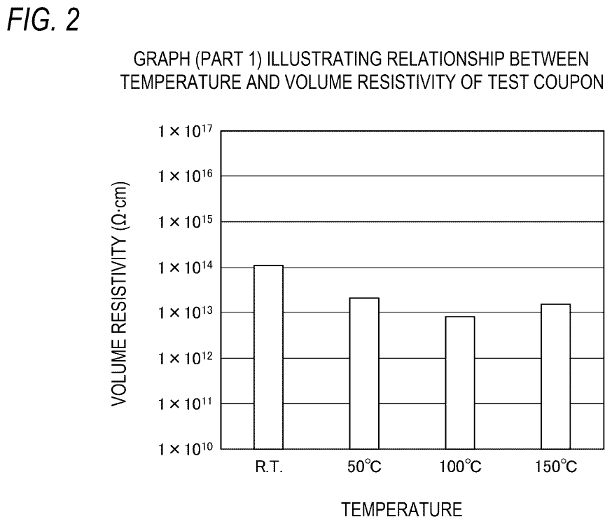

Therefore, the inventor of the present application prepared a test coupon having a ceramic base body of high-purity alumina using the conductive paste containing nickel oxide, silicon dioxide, and aluminum oxide as sintering aids in addition to a metal powder, and measured the volume resistivity thereof. The results are illustrated in FIG. 2. FIG. 2 is a graph (part 1) illustrating the relationship between temperature and volume resistivity of a test coupon. In the test coupon, as illustrated in FIG. 2, the volume resistivity was less than 1×10¹⁵ Ω·cm in a temperature range of room temperature (R.T.) to 150° C.

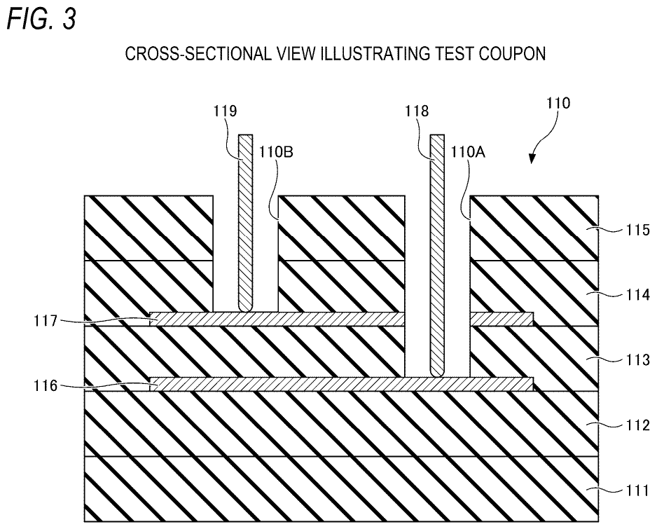

The volume resistivity illustrated in FIG. 2 was measured using the test coupon illustrated in FIG. 3. A test coupon 110 includes ceramic layers 111, 112, 113, 114, and 115 stacked in order. The test coupon 110 includes a conductor pattern 116 between the ceramic layer 112 and the ceramic layer 113, and a conductor pattern 117 between the ceramic layer 113 and the ceramic layer 114. An opening 110A reaching the conductor pattern 116 is formed in the ceramic layer 115, the ceramic layer 114, the conductor pattern 117, and the ceramic layer 113, and an opening 110B reaching the conductor pattern 117 is formed in the ceramic layer 115 and the ceramic layer 114. Then, a terminal 118 is brought into contact with the conductor pattern 116, and a terminal 119 is brought into contact with the conductor pattern 117. The volume resistivity of the ceramic layer 113 can be measured using the test coupon 110. FIG. 3 is a cross-sectional view illustrating the test coupon.

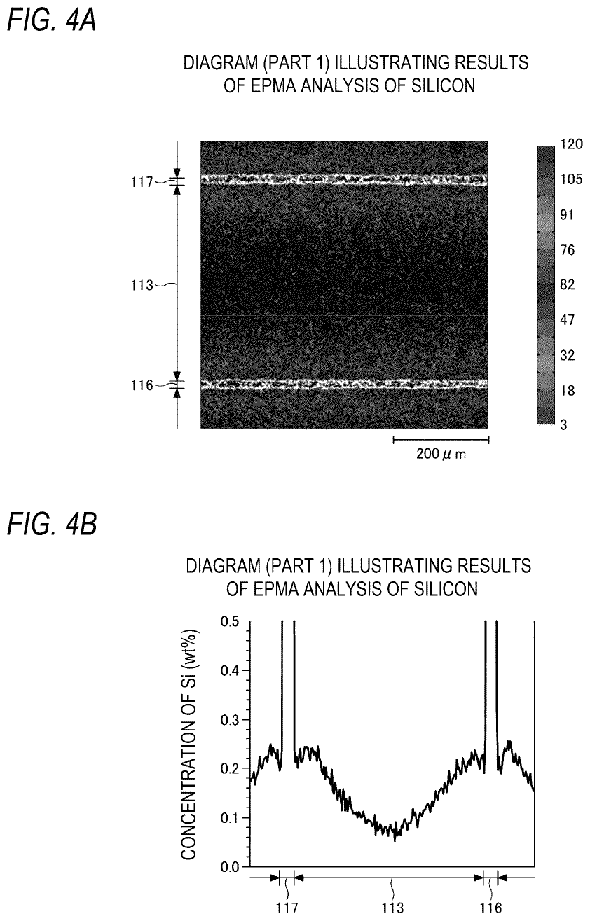

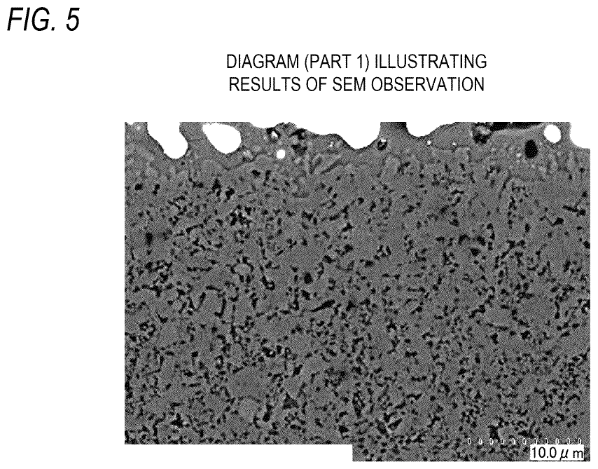

The inventor of the present application conducted intensive studies to investigate the cause of the volume resistivity of the base body in the electrostatic chuck being less than 1×10¹⁵ Ω·cm. For example, the test coupon 110 was analyzed using an electron probe micro analyzer (EPMA) and observed using a scanning electron microscope (SEM). The results are illustrated in FIGS. 4A to 5. FIGS. 4A and 4B are diagrams (part 1) illustrating the results of the EPMA analysis of silicon, in which FIG. 4A illustrates the distribution of silicon and FIG. 4B illustrates the concentration of silicon. FIG. 5 is a diagram (part 1) illustrating results of SEM observation. FIG. 5 illustrates a SEM photograph of the vicinity of the conductor pattern 117.

As illustrated in FIGS. 4A and 4B, silicon not contained in the green sheet was observed in the ceramic layer 113. The silicon is derived from silicon dioxide contained in the conductive paste. As illustrated in FIG. 5, many voids were formed in the ceramic layer 113, and the density of the ceramic layer 113 was low. The volume resistivity is increased due to these complex factors.

Based on these results, the inventor of the present application studied a conductive paste in which the sintering aid does not contain silicon dioxide. In general, one of the functions of the sintering aid is to ensure adhesion between the sintering aid and the ceramic base body, and the higher the proportion of an aluminum oxide powder, the higher the adhesion between the conductor pattern and the ceramic base body. On the other hand, the proportion of the metal powder decreases and electrical resistance of the conductor pattern increases. Therefore, it is difficult to obtain desired adhesion and the electrical resistance of the conductor pattern only by adjusting the proportion of the aluminum oxide powder.

Therefore, the inventor of the present application further conducted intensive studies. For example, three types of conductive pastes (A, B, and C) were prepared, and the volume resistivity of the conductor pattern formed using them was measured. The conductive paste contains a base, a tungsten powder, 1 mass % of nickel oxide powder, and 20 mass % of aluminum oxide powder. In the present disclosure, the proportion of the nickel oxide powder and the aluminum oxide powder is the ratio to the mass of the tungsten powder.

In each of the conductive pastes A, B, and C, the grain size of the tungsten powder was set to 1.0 μm or more and 2.0 μm or less, and the grain size of the nickel oxide powder was set to 0.1 μm or more and 0.3 μm or less. Further, in the conductive paste A, the grain sizes of all the aluminum oxide powders were set to 0.1 μm or more and 0.3 μm or less. In the conductive paste B, the grain size of 10 mass % of the aluminum oxide powder was set to 0.1 μm or more and 0.3 μm or less, and the grain size of the remaining 10 mass % of the aluminum oxide powder was set to 1.0 μm or more and 5.0 μm or less. In the conductive paste C, the grain sizes of all the aluminum oxide powders were set to 1.0 μm or more and 5.0 μm or less.

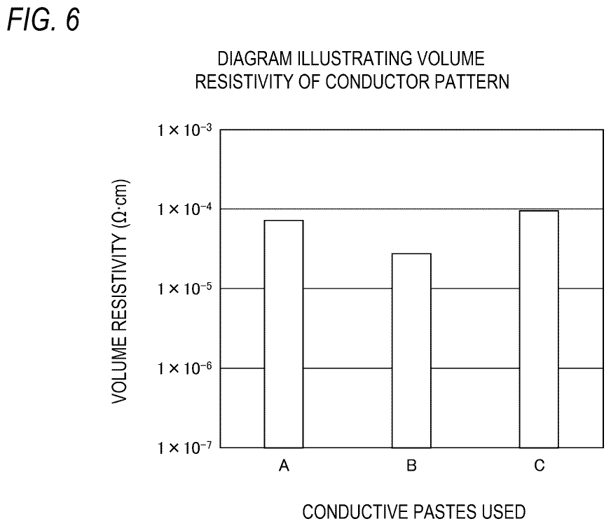

FIG. 6 illustrates the volume resistivity of the conductor pattern. As illustrated in FIG. 6, the conductor pattern formed using the conductive paste B had a lower volume resistivity than the conductor pattern formed using the conductive paste A or C. It is considered that this is because when the aluminum oxide powder having a grain size of less than 1 μm and the aluminum oxide powder having a grain size of 1 μm or more are contained in the conductive paste, the tungsten powders easily come into contact with each other and the aluminum oxide powder is easily sintered.

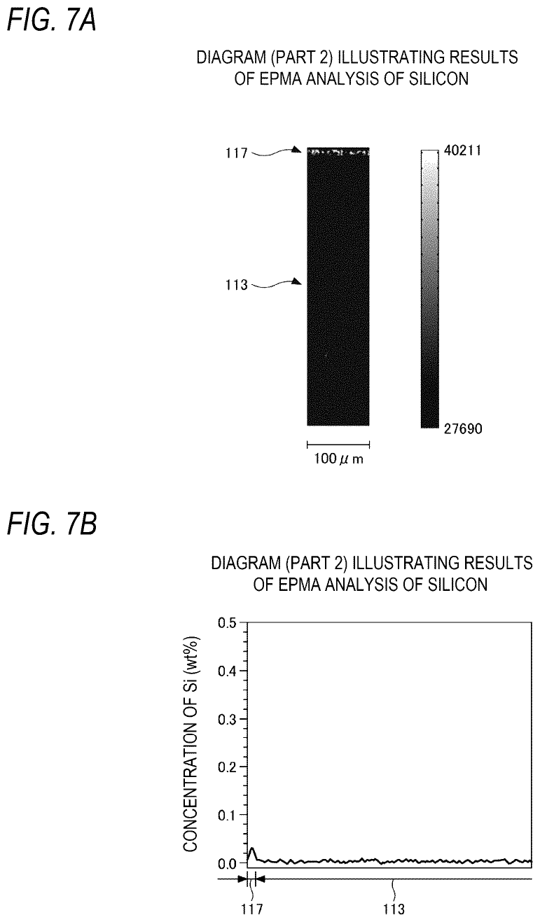

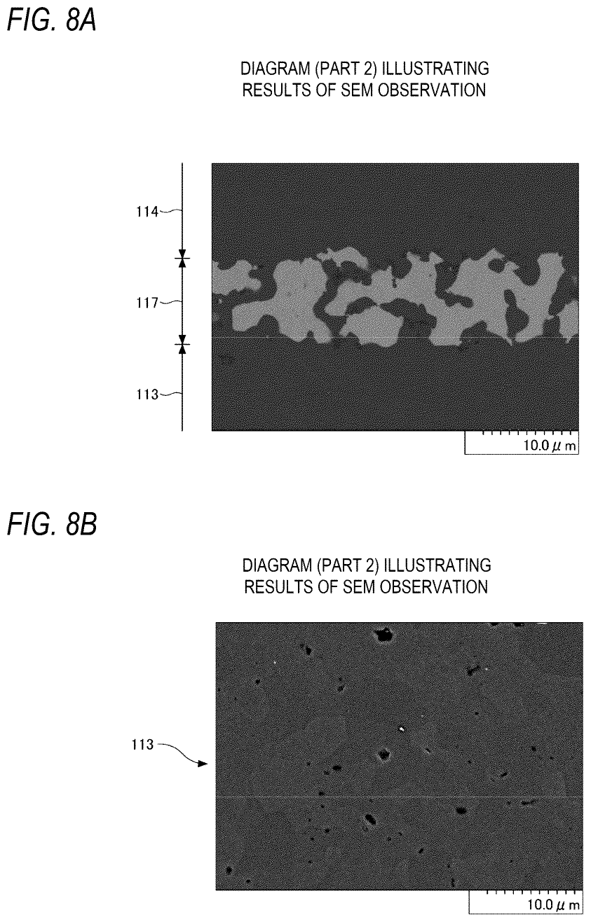

The inventor of the present application produced a test coupon 110 having a diameter of 304.8 mm (12 inches) using the conductive paste containing the aluminum oxide powder (10 mass %) having the grain size of 0.1 μm or more and 0.3 μm or less and the aluminum oxide powder (10 mass %) having the grain size of 1.0 μm or more and 5.0 μm or less, and performed the EPMA analysis and the SEM observation. The results are illustrated in FIGS. 7A to 8B. FIGS. 7A and 7B are diagrams (part 2) illustrating the results of the EPMA analysis of silicon, in which FIG. 7A illustrates the distribution of silicon and FIG. 7B illustrates the concentration of silicon. FIGS. 8A and 8B are diagrams (part 2) illustrating results of the SEM observation. FIG. 8A illustrates a SEM photograph of the conductor pattern 117 and the vicinity thereof, and FIG. 8B illustrates a SEM photograph of the vicinity of the center of the ceramic layer 113 in a thickness direction.

As illustrated in FIGS. 7A and 7B, silicon at the level of an impurity was observed in the conductor pattern 117, but substantially no silicon was observed in the ceramic layer 113. As illustrated in FIGS. 8A and 8B, there were few voids, and the ceramic layers 113 and 114 had a sufficient density.

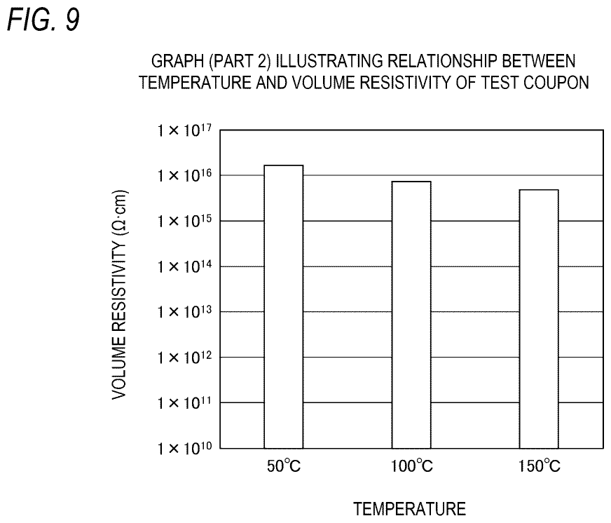

Further, the inventor of the present application prepared the test coupon 110 using a conductive paste containing an aluminum oxide powder (5 mass %) having the grain size of 0.1 μm or more and 0.3 μm or less and the aluminum oxide powder (5 mass %) having the grain size of 1.0 μm or more and 5.0 μm or less, and measured the volume resistivity of the ceramic layer 113. The results are illustrated in FIG. 9. FIG. 9 is a graph (part 2) illustrating the relationship between the temperature and the volume resistivity of the test coupon. In the test coupon 110, as illustrated in FIG. 9, the volume resistivity was 1×10¹⁵ Ω·cm or more in the temperature range of 50° C. to 150° C.

As a result of these intensive studies, the inventor of the present application found that when the aluminum oxide powder having the grain size of less than 1 μm and the aluminum oxide powder having the grain size of 1 μm or more were contained in the conductive paste, sufficient adhesion can be obtained even if the conductive paste does not contain silicon dioxide, and low electrical resistance can be obtained in the conductor pattern.

Hereinafter, an embodiment of the present disclosure will be specifically described with reference to the accompanying drawings. It should be noted that, in the present specification and the drawings, components having substantially the same functional configuration are denoted by the same reference signs, and redundant description may be omitted.

### Structure of Substrate Fixing Device

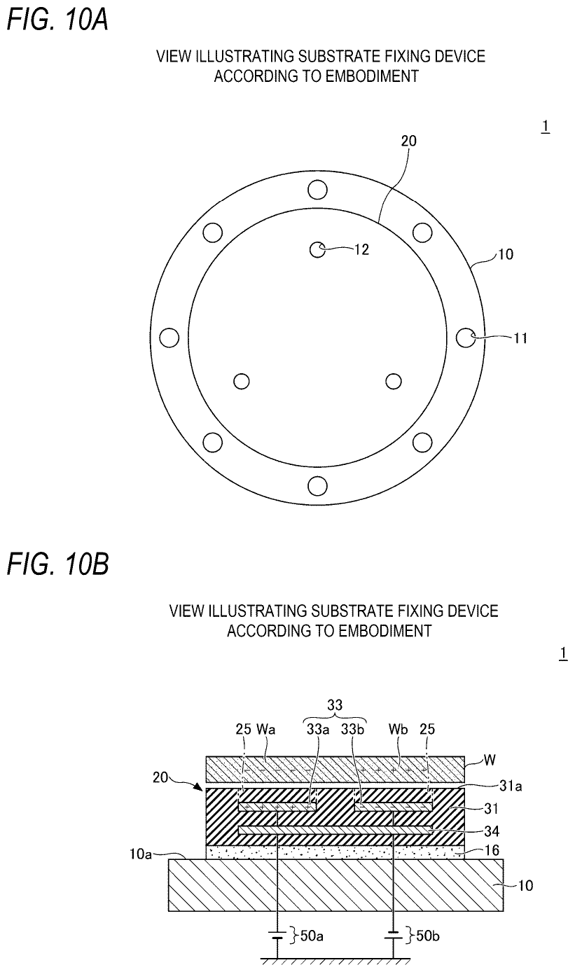

The present embodiment relates to a substrate fixing device. FIGS. 10A and 10B are views each illustrating the substrate fixing device according to an embodiment. FIG. 10A is a plan view, and FIG. 10B is a cross-sectional view.

As illustrated in FIGS. 10A and 10B, a substrate fixing device 1 according to the first embodiment includes a base plate 10 and an electrostatic chuck 20. The substrate fixing device 1 suctions and holds a substrate W (for example, a semiconductor wafer or the like), which is a suction object, by the electrostatic chuck 20.

The base plate 10 and the electrostatic chuck 20 are formed in a circular shape in the plan view. That is, the base plate 10 and the electrostatic chuck 20 are formed in a disk shape. The base plate 10 is exposed around the electrostatic chuck 20. In a peripheral portion of the base plate 10, attachment holes 11 for attaching the base plate 10 to a chamber of a semiconductor manufacturing device are arranged along the peripheral portion. Further, the electrostatic chuck 20 and the base plate 10 have a plurality of (three in FIG. 10A) lift pin openings 12 in a central portion thereof. A lift pin (not illustrated) that moves the substrate W in an upper-lower direction is inserted into the opening 12. By raising the substrate W from the electrostatic chuck 20 by the lift pins, the substrate W can be automatically transferred by a transfer device.

In the present disclosure, the “plan view” refers to a view of an object from a normal direction of an upper surface 10a of the base plate 10, and a “planar shape” refers to a shape of the object viewed from the normal direction of the upper surface 10a of the base plate 10.

The base plate 10 is a member for mounting the electrostatic chuck 20. A thickness of the base plate 10 is, for example, about 20 mm to 40 mm. The base plate 10 is formed of, for example, a metal material such as aluminum or a super hard alloy, a composite material of the metal material and a ceramic material, or the like, and can be used as an electrode or the like for controlling plasma. For example, in terms of availability, ease of processing, good thermal conductivity, and the like, it is preferable to use aluminum or an alloy thereof and to perform an alumite treatment (insulating layer formation) on a surface thereof.

For example, by supplying a predetermined high frequency power to the base plate 10, it is possible to control energy for causing generated ions or the like in a plasma state to collide with the substrate W suctioned on the electrostatic chuck 20, and to effectively perform etching processing of the substrate W.

A gas supply passage for introducing an inert gas for cooling the substrate W suctioned on the electrostatic chuck 20 may be provided inside the base plate 10. When an inert gas such as helium (He) or argon (Ar) is introduced into the gas supply passage from the outside of the substrate fixing device 1 and the inert gas is supplied to a back surface of the substrate W suctioned on the electrostatic chuck 20, the substrate W can be cooled.

The electrostatic chuck 20 suctions and holds the substrate W, which is the suction object. A planar shape of the electrostatic chuck 20 is determined according to the shape of the substrate W, and is, for example, circular. The diameter of the substrate W, which is the suction object of the electrostatic chuck 20, is, for example, 203.2 mm (8 inches), 304.8 mm (12 inches), or 457.2 mm (18 inches).

The electrostatic chuck 20 is a ceramic substrate including a base body 31, an electrostatic electrode 33, and a heating element 34. An upper surface 31a of the base body 31 is a placement surface on which the substrate W is placed. The electrostatic chuck 20 is, for example, a Coulomb force type electrostatic chuck. The electrostatic chuck 20 may be a Johnsen-Rahbek type electrostatic chuck.

The base body 31 is made of, for example, ceramic containing aluminum oxide (Al₂O₃), aluminum nitride (AlN), yttrium aluminum garnet (YAG), or the like as a main component. Among these, it is preferable that the base body 31 is made of aluminum oxide, which is easy to sinter, is relatively inexpensive, and has high electrical resistance, as the main component, and it is more preferable that the base body 31 is made of aluminum oxide. Here, the term “made of aluminum oxide” means a ceramic to which an inorganic component other than aluminum oxide is not added.

The purity of aluminum oxide in the base body 31 is preferably 99.5% or more. The purity of 99.5% or more indicates that the base body 31 is formed without adding the sintering aid. In addition, the purity of 99.5% or more means that unintended impurities may be contained in a manufacturing process or the like. The base body 31 preferably has a relative density of 97% or more with respect to aluminum oxide. In the base body 31, the average grain size of aluminum oxide is preferably 1.0 μm or more and 3.0 μm or less.

The electrostatic electrode 33 is a thin-film electrode formed of a conductor pattern, and is embedded in the base body 31. In the present embodiment, the electrostatic electrode 33 is of a bipolar type and includes a first electrostatic electrode 33a and a second electrostatic electrode 33b. As the electrostatic electrode 33, a unipolar type including one electrostatic electrode may be used.

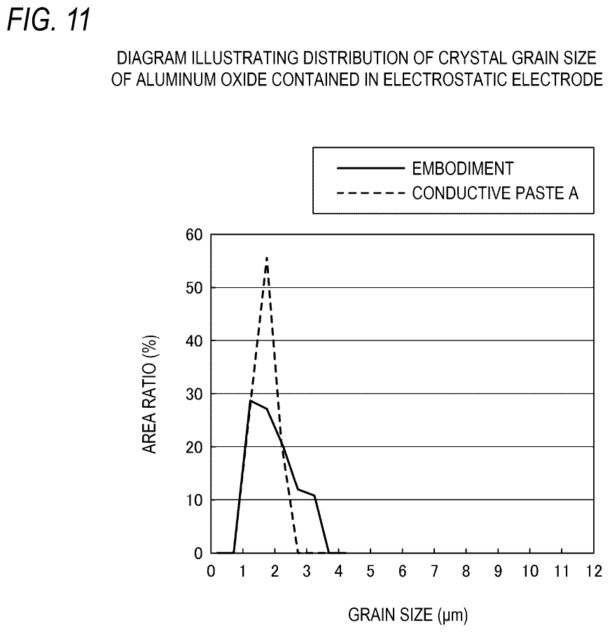

The electrostatic electrode 33 contains tungsten. The electrostatic electrode 33 contains, for example, tungsten as a main component. Here, the main component means a component occupying 50 mass % or more of all substances constituting the electrostatic electrode 33. The electrostatic electrode 33 also includes aluminum oxide. The aluminum oxide is crystallized. FIG. 11 is a graph illustrating the distribution of crystal grain size of the aluminum oxide contained in the electrostatic electrode. An area ratio illustrated on the vertical axis of FIG. 11 is the ratio of a total area occupied by the crystal grains of the crystal grain size to the area of an observation region measured by an electron back-scatter diffraction (EBSD) method. As illustrated in FIG. 11, the crystal grain size of the crystal grains of aluminum oxide ranges from less than 1 μm to 3 μm or more. That is, the electrostatic electrode 33 includes first aluminum oxide crystal grains having a crystal grain size of less than 1 μm, second aluminum oxide crystal grains having a crystal grain size of 1 μm or more and less than 3 μm, and third aluminum oxide crystal grains having a crystal grain size of 3 μm or more. For comparison, FIG. 11 also illustrates the distribution of the crystal grain size of aluminum oxide when an electrostatic electrode is formed using the conductive paste A described above. The area ratio of the first aluminum oxide crystal grains in the cross section of the conductor pattern forming the electrostatic electrode 33 is, for example, 0.1% or more and 5.0% or less, the area ratio of the second aluminum oxide crystal grains in the cross section is, for example, more than 50% and 95% or less, and the area ratio of the third aluminum oxide crystal grains in the cross section is, for example, 5% or more and less than 50%.

The first electrostatic electrode 33a is connected to a positive electrode side of a power supply 50a provided outside the substrate fixing device 1. The second electrostatic electrode 33b is connected to a negative electrode side of a power supply 50b provided outside the substrate fixing device 1. A negative electrode side of the power supply 50a and a positive electrode side of the power supply 50b are connected outside the substrate fixing device 1, and a connection point is a ground potential.

The heating element 34 is a heater that is embedded in the base body 31 and generates heat when a current flows. The heating element 34 is disposed below (at a base plate 10 side of) the first electrostatic electrode 33a and the second electrostatic electrode 33b. The heating element 34 is a conductor formed in a film shape. The heating element 34 is provided as a plurality of heater electrodes capable of independently controlling heating of a plurality of regions (heater zones) of the base body 31 in a plane. The heating element 34 may be provided as one heater electrode. The heating element 34 can be formed of, for example, a material similar to that of the electrostatic electrode 33.

A positive (+) voltage is applied from the power supply 50a to the first electrostatic electrode 33a, and a negative (−) voltage is applied from the power supply 50b to the second electrostatic electrode 33b. Accordingly, the first electrostatic electrode 33a is charged with the positive (+) charge, and the second electrostatic electrode 33b is charged with the negative (-) charge. Accordingly, the negative (−) charge is induced in a portion Wa of the substrate W corresponding to the first electrostatic electrode 33a, and the positive (+) charge is induced in a portion Wb of the substrate W corresponding to the second electrostatic electrode 33b.

In the electrostatic chuck 20, the substrate W and the electrostatic electrode 33 can be regarded as two electrodes of a capacitor, and a ceramic portion 25 between the substrate W and the electrostatic electrode 33 of the electrostatic chuck 20 can be regarded as a dielectric of the capacitor. Then, in the capacitor, the substrate W is electrostatically absorbed on the electrostatic chuck 20 by Coulomb force generated between the electrostatic electrode 33 and the substrate W via the ceramic portion 25. A suction-holding force increases as the voltage applied to the electrostatic electrode 33 increases.

Further, when a current is supplied to the heating element 34 from a power supply provided outside the substrate fixing device 1, the heating element 34 generates heat to heat the electrostatic chuck 20. The substrate W is controlled to a predetermined temperature by the temperature of the electrostatic chuck 20. A heating temperature of the electrostatic chuck 20 is set within a range of 50° C. to 200° C., for example, 150° C.

The electrostatic chuck 20 is provided on the upper surface 10a of the base plate 10 via an adhesive layer 16. The adhesive layer 16 is, for example, a silicone-based adhesive. The thickness of the adhesive layer 16 is, for example, about 0.1 mm to 2.0 mm. The adhesive layer 16 has an effect of adhering the base plate 10 and the electrostatic chuck 20 and reducing thermal stress caused by a difference in thermal expansion coefficient between the electrostatic chuck 20 made of ceramic and the base plate 10 made of aluminum. The electrostatic chuck 20 may be fixed to the base plate 10 by screws.

### Method for Manufacturing Electrostatic Chuck

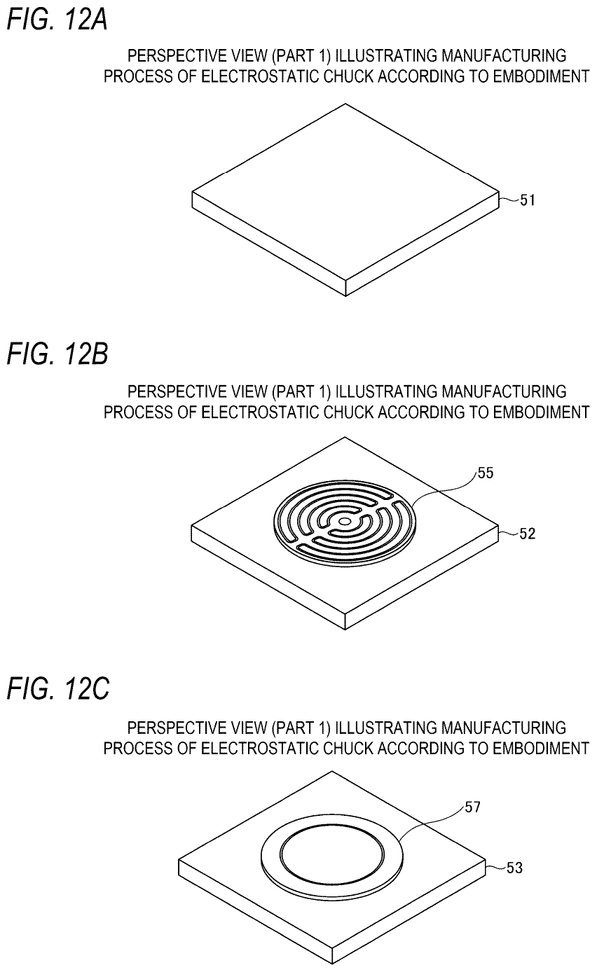

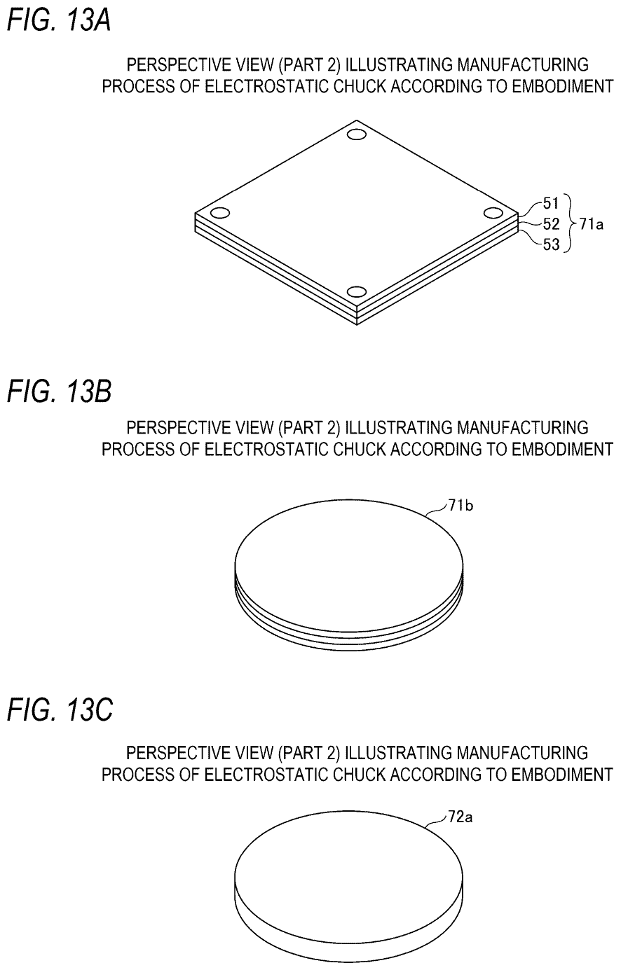

Next, a method for manufacturing the electrostatic chuck 20 will be described. FIGS. 12A to 13C are perspective views illustrating the manufacturing process of the electrostatic chuck according to the embodiment.

First, as illustrated in FIG. 12A, a green sheet 51 made of a ceramic material and an organic material is prepared. The green sheet 51 is formed in, for example, a rectangular plate shape. The ceramic material of the green sheet 51 is aluminum oxide and does not contain the sintering aid. The green sheet 51, when being fired, undergoes removal of the organic component, sintering and densification of the ceramic material, and becomes a portion of the base body 31 on which the substrate W illustrated in FIGS. 10A and 10B is mounted.

Next, as illustrated in FIG. 12B, a green sheet 52 made of a material and having a shape similar to those of the green sheet 51 is prepared, and a conductive paste is printed on an upper surface of the green sheet 52 by, for example, a printing method (screen printing) to form a conductor pattern 55. The green sheet 52 becomes a portion of the base body 31 between the electrostatic electrode 33 and the heating element 34 by being fired. The conductor pattern 55 becomes the electrostatic electrode 33 by being fired. The conductor pattern 55 may be formed on a lower surface of the green sheet 51.

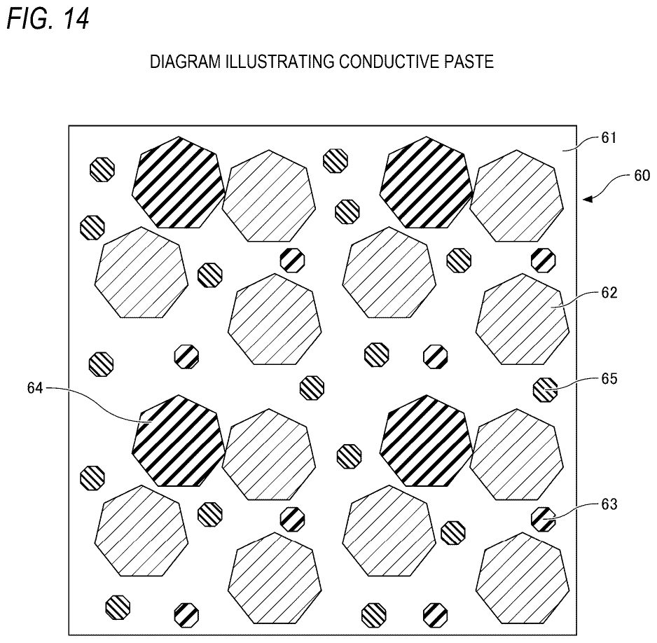

The conductive paste is used to form the conductor pattern 55. FIG. 14 is a diagram illustrating a conductive paste. The conductive paste 60 includes a base 61, metal powders 62, first aluminum oxide powders 63, second aluminum oxide powders 64, and nickel oxide powders 65. The metal powder 62 is dispersed in the base 61 and contains tungsten. The first aluminum oxide powder 63 is dispersed in the base 61, and the grain size of the first aluminum oxide powder 63 is less than 1 μm. The second aluminum oxide powder 64 is dispersed in the base 61, and the grain size of the second aluminum oxide powder 64 is 1 μm or more. The nickel oxide powder 65 is dispersed in the base 61, and the grain size of the nickel oxide powder 65 is less than 1 μm.

The base 61 contains, for example, an organic material. For example, the grain size of the metal powder 62 is 1.0 μm or more and 2.0 μm or less. For example, the grain size of the first aluminum oxide powder 63 is 0.1 μm or more and 0.3 μm or less, the grain size of the second aluminum oxide powder 64 is 1.0 μm or more and 5.0 μm or less, and the grain size of the nickel oxide powder 65 is 0.1 μm or more and 0.3 μm or less.

Among the metal powder 62, the first aluminum oxide powder 63, the second aluminum oxide powder 64, and the nickel oxide powder 65, the total mass of the metal powder 62 is the largest. The ratio of the total mass of the first aluminum oxide powder 63 and the second aluminum oxide powder 64 to the total mass of the metal powder 62 is, for example, 5 mass % or more and 40 mass % or less, and preferably 10 mass % or more and 20 mass % or less. The total mass of the first aluminum oxide powder 63 is preferably 3/7 times or more and 7/3 times or less, more preferably 2/3 times or more and 3/2 times or less the total mass of the second aluminum oxide powder 64. Particularly preferably, the total mass of the first aluminum oxide powder 63 is equal to the total mass of the second aluminum oxide powder 64.

The conductive paste 60 does not intentionally contain silicon, but may inevitably contain silicon. Preferably, the ratio of the total mass of silicon to the total mass of the metal powder 62 in the base 61 is 0.1 mass % or less.

Next, as illustrated in FIG. 12C, a green sheet 53 made of a material and having a shape similar to those of the green sheet 51 is prepared, and a conductive paste is printed on an upper surface of the green sheet 53 by, for example, a printing method (screen printing) to form a conductor pattern 57. As the conductive paste forming the conductor pattern 57, a conductive paste made of the same material as the conductive paste forming the conductor pattern 55 described above can be used. The green sheet 53 becomes a portion of the base body 31 to be bonded to the base plate 10 by firing. The conductor pattern 57 becomes the heating element 34 by being fired. The conductor pattern 57 may be formed on a lower surface of the green sheet 52.

Next, as illustrated in FIG. 13A, the green sheets 51 to 53 are stacked to form a structure 71a. The green sheets 51 to 53 are bonded to each other by being pressurized while being heated. Next, as illustrated in FIG. 13B, a periphery of the structure 71a is cut to form a disk-shaped structure 71b.

Next, the structure 71b illustrated in FIG. 13B is fired to obtain a ceramic substrate 72a illustrated in FIG. 13C. The temperature during the firing is, for example, 1600° C. In this step, the electrostatic electrode 33 is obtained by sintering the conductor pattern 55, and the heating element 34 is obtained by sintering the conductor pattern 57.

Next, various processes are performed on the ceramic substrate 72a to complete the electrostatic chuck 20. For example, upper and lower surfaces of the ceramic substrate 72a are polished to form a placement surface and an adhering surface. The lift pin openings 12 illustrated in FIG. 10A are formed in the ceramic substrate 72a.

In this way, the electrostatic chuck 20 can be manufactured.

The substrate fixing device 1 can be manufactured by bonding the base plate 10 and the electrostatic chuck 20 using the adhesive layer 16.

In the electrostatic chuck 20 and the substrate fixing device 1, the conductive paste 60 is used to form the electrostatic electrode 33, and the conductive paste 60 includes the base 61, the metal powder 62, the first aluminum oxide powder 63, the second aluminum oxide powder 64, and the nickel oxide powder 65. Further, the grain size of the first aluminum oxide powder 63 is less than 1 μm, and the grain size of the second aluminum oxide powder 64 is 1 μm or more. Therefore, in the electrostatic chuck 20 and the substrate fixing device 1, the electrostatic electrode 33 includes the first aluminum oxide crystal grains having a crystal grain size of less than 1 μm, the second aluminum oxide crystal grains having a crystal grain size of 1 μm or more and less than 3 μm, and the third aluminum oxide crystal grains having a crystal grain size of 3 μm or more. Therefore, diffusion of silicon into the green sheet 51, 52 or 53 during firing is avoided, and the volume resistivity of the base body 31 can be made low, preferably 1×10¹⁵ Ω·cm or more at a temperature of about 150° C. Further, the electrostatic electrode 33 can have a low volume resistivity.

The material of the metal powder is not limited to tungsten. Examples of the material of the metal powder also include a tungsten alloy, molybdenum, and a molybdenum alloy. Both the powder containing tungsten and the powder containing molybdenum may be used. When the material of the metal powder is molybdenum or a molybdenum alloy, the conductive paste 60 can be sintered even if the conductive paste 60 does not contain the nickel oxide powder 65.

The inventor of the present application conducted an experiment for confirming the strength when tungsten or molybdenum was used as the material of the metal powder 62 of the conductive paste 60. In this experiment, a tensile test was performed on a sample D using tungsten as the material of the metal powder 62, a sample E using molybdenum as the material of the metal powder 62, and a sample F as a reference sample. In the sample F, tungsten was used as the material of the metal powder, and aluminum oxide powder, nickel oxide powder, and silicon dioxide powder were used as the sintering aids.

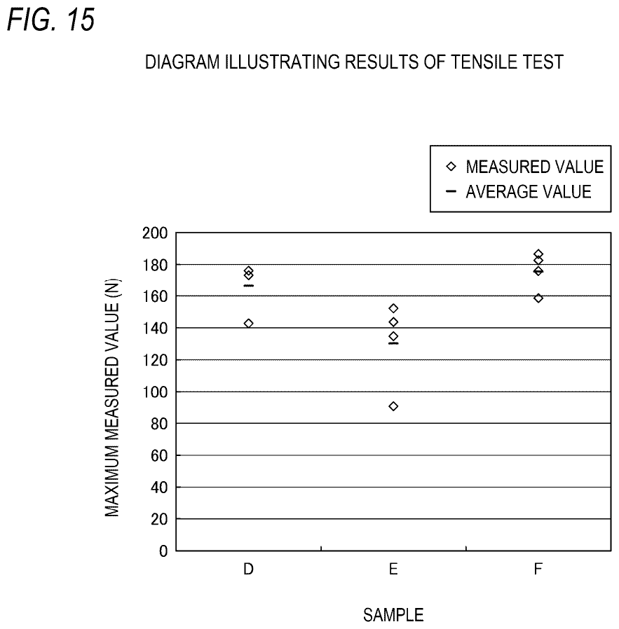

In the preparation of the sample, a conductive paste was applied to one surface of the green sheet, and the green sheet and the conductive paste were simultaneously fired to obtain a laminate of a ceramic layer and a conductor pattern. In the tensile test, the sample was placed on the stage such that the ceramic layer was in contact with the stage, the sample was screwed to the stage from above the conductor patterns at two positions, a jig was joined to the conductor patterns by solder between the two positions, and the jig was pulled in a direction away from the stage. Then, a maximum value of the tensile load measured until breakage was obtained as a maximum measured value. In addition, each sample was measured four times, and an average value thereof was calculated. Results are illustrated in FIG. 15. FIG. 15 is a diagram illustrating the results of the tensile test.

In each sample, the jig was broken before peeling occurred at an interface between the ceramic layer and the conductor pattern. As illustrated in FIG. 15, the maximum measured value was 80 N or more in all the samples, and the maximum measured value of 120 N or more was obtained except for one of the sample E. This indicates that good adhesion can be obtained between the base body and the conductor pattern even when tungsten, molybdenum, or both are used as the material of the metal powder.

Although the preferred embodiments and the like have been described in detail, the present disclosure is not limited to the embodiments and the like described above, and various modifications and substitutions can be made to the embodiments and the like described above without departing from the scope of the claims.

What is claimed is:

1. A ceramic substrate comprising:
a base body formed of ceramic; and
a conductor pattern embedded in the base body and containing tungsten, molybdenum, or both, wherein
the conductor pattern includes
a first aluminum oxide crystal grain having a crystal grain size of less than 1 μm,
a second aluminum oxide crystal grain having a crystal grain size of 1 μm or more and less than 3 μm, and
a third aluminum oxide crystal grain having a crystal grain size of 3 μm or more.

2. The ceramic substrate according to claim 1, wherein a main component of the base body is aluminum oxide.

3. The ceramic substrate according to claim 2, wherein a purity of the aluminum oxide in the base body is 99.5% or more.

4. The ceramic substrate according to claim 1, wherein a proportion of silicon in the conductor pattern is 0.05 mass % or less.

5. The ceramic substrate according to claim 1, wherein a volume resistivity of the base body is 1×10¹⁵ Ω·m or more.

6. An electrostatic chuck, wherein
in the ceramic substrate according to claim 1, the conductor pattern is an electrostatic electrode.

7. The ceramic substrate according to claim 1, wherein
an area ratio of the first aluminum oxide crystal grain in a cross section of the conductor pattern is 0.1% or more and 5.0% or less.

8. The ceramic substrate according to claim 1, wherein
an area ratio of the second aluminum oxide crystal grain in a cross section of the conductor pattern is more than 50% and 95% or less.

9. The ceramic substrate according to claim 1, wherein
an area ratio of the third aluminum oxide crystal grain in a cross section of the conductor pattern is 5% or more and less than 50%.

10. A substrate fixing device comprising:
a base plate; and
the electrostatic chuck according to claim 6 mounted on one surface of the base plate.

11. A conductive paste comprising:
a base;
a metal powder dispersed in the base and containing tungsten, molybdenum, or both;
a first aluminum oxide powder dispersed in the base and having a grain size of less than 1 μm; and
a second aluminum oxide powder dispersed in the base and having a grain size of 1 μm or more.

12. The conductive paste according to claim 11, wherein
a grain size of the first aluminum oxide powder is 0.1 μm or more and 0.3 μm or less, and
a grain size of the second aluminum oxide powder is 1.0 μm or more and 5.0 μm or less.

13. The conductive paste according to claim 12, wherein
a total mass of the first aluminum oxide powder is 3/7 times or more and 7/3 times or less a total mass of the second aluminum oxide powder.

14. The conductive paste according to claim 11, wherein
a ratio of a total mass of silicon to a total mass of the metal powder in the base is 0.1 mass % or less.

15. The conductive paste according to claim 11, further comprising:
a nickel oxide powder dispersed in the base.
